(19) United States
(12) Patent Application Publication
(10) Pub. No.: US 2007/0134853 A1
(43) Pub. Date: Jun. 14, 2007

(54) Power semiconductor device having reduced on-resistance and method of manufacturing the same

(75) Inventor: Yi-Yeu Lin, Congshan Township (TW)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/297,398

(22) Filed: Dec. 9, 2005

(51) Int. Cl. H01L 21/8232; H01L 21/335

(52) U.S. Cl. 438/142

(57) ABSTRACT

A power semiconductor device having reduced on-resistance (Rₒₙ) and a method of manufacturing the same is provided. The method is provided after forming the gate region for inclinedly implanting the dopant of the first conductivity type into the JFET region above the epitaxial layer. The gate region blocks the dopant from entering the channel region, thus the dopant is not directly implanted into the channel region. Furthermore, the breakdown voltage and the threshold voltage in the channel region will not be affected by increasing the quantity of dopant into the JFET region in the ion implantation, thereby achieving a decrease in the on-resistance of the DMOS structure.

### BACKGROUND OF THE INVENTION

1. Field of the Invention

The present invention relates to the field of power semiconductor devices. More particularly, the present invention relates to a power semiconductor device having reduced on-resistance (Rₒₙ) and a method of manufacturing the same.

2. Description of the Related Art

Power semiconductor devices, e.g., metal oxide semiconductor field effect transistors (MOSFETs), are well known in the semiconductor industry. One type of MOSFET is a double-diffused metal oxide semiconductor (DMOS) transistor (hereafter referred to as a DMOS structure), which generally includes an n-channel DMOS structure and a p-channel DMOS structure. In addition, the insulated gate bipolar transistor (IGBT) is another structure that is very similar to the DMOS structure. Furthermore, the power semiconductor device has several inherent advantages, such as low power consumption via a driver, which is used without adding heat sinks, and is thus capable of allowing electronic products to be light, thin, short and small. In order to satisfy stricter requirements of low power consumption and higher frequencies of electronic products, the power semiconductor device with improved characteristics, such as high breakdown voltage, low on-resistance and small switching loss, is desired

FIG. 1 shows a sectional view of a conventional n-channel DMOS structure. As shown, an n-type epitaxial layer 20a overlies a semiconductor substrate 10a (defined as an n-type drain region). A source regions 40a is formed within p-type body regions 30a. A gate region 50a (including an insulating layer and a polysilicon structure) overlaps the source regions 40a, and extends over surface portions of the body regions 30a. The surface area of the body regions 30a directly underneath the gate region 50a defines a transistor channel region 31a. The area between the two adjacent body regions 30a under the gate region 50a or the area above the epitaxial layer 20a is commonly referred to as a junction field effect transistor (hereafter called to the JFET region).

One important electrical characteristic of the power semiconductor device is its on-resistance (Rₒₙ), which is defined as the total resistance encountered by the carriers as they flow from source regions 40a to the drain region 10a. As depicted pictorially in FIG. 1, the resistance Rₒₙ in the planar structure is made up of the resistance R₁ through the channel region 31a, the resistance R₂ is created vertically through the pinched portion of the epitaxial layer 20a between the two adjacent p-type body regions 30a, the resistance R₃ is created vertically through the remainder portion of the epitaxial layer 20a to the substrate 10a, the resistance R₄ is created vertically through the substrate 10a to the drain electrode. It is desirable that such transistors have low source-to-drain resistance Rₒₙ when turned on, yet the resistance R₁ (i.e., the resistance in the channel region) or R₂ (i.e., the resistance in the JFET region) is a key resistance for decreasing the resistance Rₒₙ of the power semiconductor device.

FIG. 2 shows a conventional method for decreasing the resistance in the JFET region. This method is provided prior to the step of forming the gate region 50a for introducing an n-type dopant vertically downwardly into the JFET region above the epitaxial layer 20a and the channel region 31a by ion implantation or a diffusion process. As is well known to those of ordinary skill, the resistance in the JFET region decreases with increasing the n-type dopant concentration in the JFET region, so that the purpose of decreasing the on-resistance of the DMOS structure can be achieved via the above method.

However, regarding the above method, although the resistance in the JFET region can be decreased, the high-concentration of n-type dopant also neutralizes the p-type dopant in the body regions 30a, causing a decrease in the p-type dopant concentration of a top of the body regions 30a. Because the n-type dopant is directly implanted into the channel region 31a above the body regions 30a, the outer edge of the channel region 31a will be pushed-in the body regions 30a (referred to as the J portion in FIG. 2). Next, with increasing quantity of the n-type dopant, the p-type dopant concentration of the channel region 31a will gradually become low, resulting in a reduction in the threshold voltage and the breakdown voltage, finally producing a punch-through effect in the channel region 31a.

Accordingly, since the magnitude of the on-resistance and the breakdown voltage vary in a similar manner with respect to the dopant concentration, decreasing the on-resistance of the DMOS structure by decreasing the p-type dopant concentration in the channel region 31a causes an undesirable decrease in the breakdown voltage and results in the punch-through effect in the channel region 31a.

Thus, the DMOS structure that decreases the resistance in the JFET region but still maintains the high breakdown voltage is desired.

### SUMMARY OF THE INVENTION

In accordance with the present invention, a power semiconductor device having reduced on-resistance and a method of manufacturing the same, are provided in that the breakdown voltage and the threshold voltage in the channel region will not be affected by increasing quantities of dopant into the JFET region in the ion implantation, thereby achieving a decrease in the on-resistance of the DMOS structure.

To achieve the above purpose, the method of the present invention provides for inclinedly implanting the dopant of the first conductivity type (which is an n-type in the n-channel DMOS structure, and is a p-type in the p-channel DMOS structure) into the JFET region above the epitaxial layer, thereby forming a medium-concentration epitaxial region of the first conductivity type. When the method is performed in its entirety, the step of forming the gate region is performed prior to the inclinedly implanting step for blocking the dopant into the channel region. The dopant is not directly implanted into the channel region, thus the threshold voltage and the breakdown voltage will not be decreased, and the punch-through effect will also be avoided.

In accordance with another aspect of the invention, the power semiconductor device can be an n-channel DMOS structure, a p-channel DMOS structure or an IGBT structure, made according to the above method, which includes a substrate; an epitaxial layer of a first conductivity type formed over the substrate, a gate region formed adjacent to an upper surface of the epitaxial layer, one or more body regions of a second conductivity type formed within the epitaxial layer, a plurality of source regions of the first conductivity type formed within the body regions, wherein the surface area of the body regions directly underneath the gate region is defined as a channel region; and a medium-concentration epitaxial region of the first conductivity type is formed by inclinedly implanting dopant of the first conductivity type into a JFET region above the epitaxial layer.

To provide a further understanding of the invention, the following detailed description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a sectional view of a conventional n-channel DMOS structure;

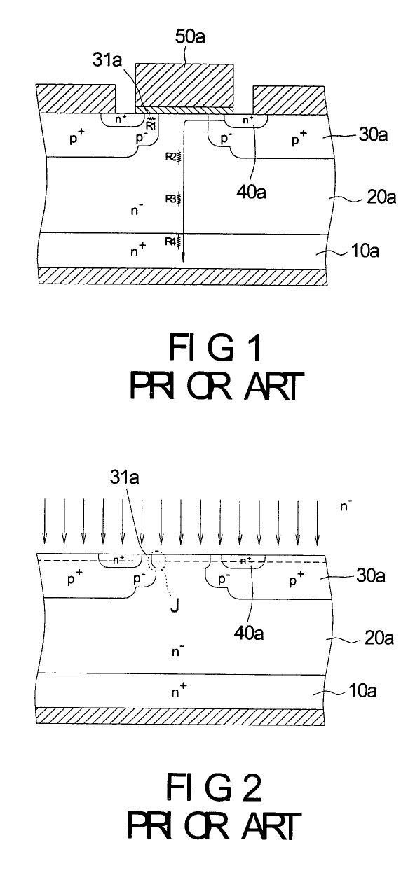

FIG. 2 shows a conventional method for decreasing the resistance in the JFET region;

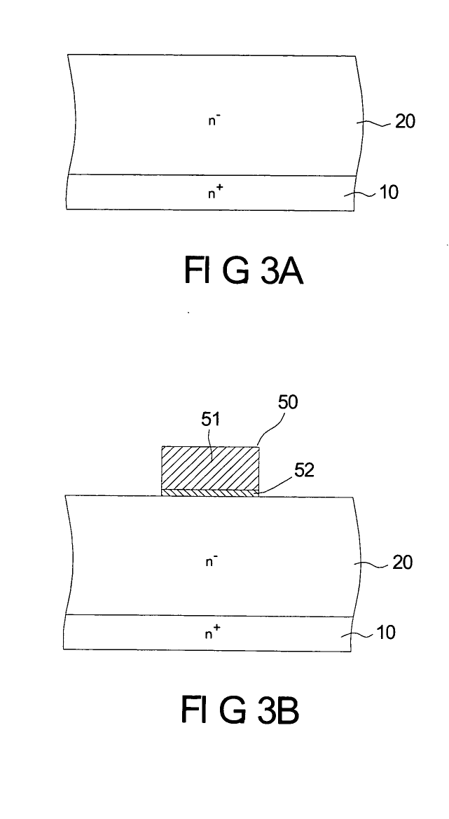

FIGS. 3A-3E shows a series of exemplary steps that are performed to form the n-channel DMOS structure; and

FIG. 4 is a sectional view of the n-channel DMOS transistor structure where a horizontal distance in the channel region is relatively small.

### DETAILED DESCRIPTION OF THE EMBODIMENTS

Referring now to the drawings wherein the showings concern an n-channel DMOS structure (which is defined as a high-concentration drain region of a first conductivity type, wherein the first conductivity type is an n-type and the second conductivity type is a p-type) for purposes of illustrating preferred embodiments of the present invention only, and not for purposes of limiting the same (for example, a p-channel DOMS structure is defined as the high-concentration drain region of the first conductivity type, wherein the first conductivity type is p-type and the second conductivity type is n-type, or an IGBT structure is defined as the high-concentration drain region of the second conductivity type).

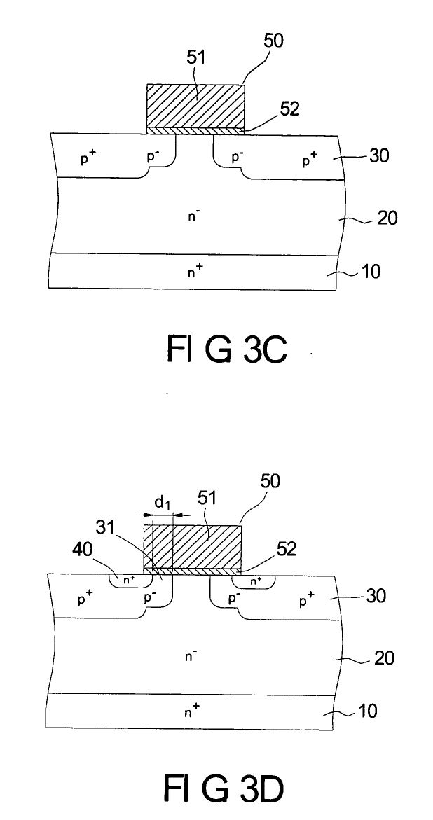

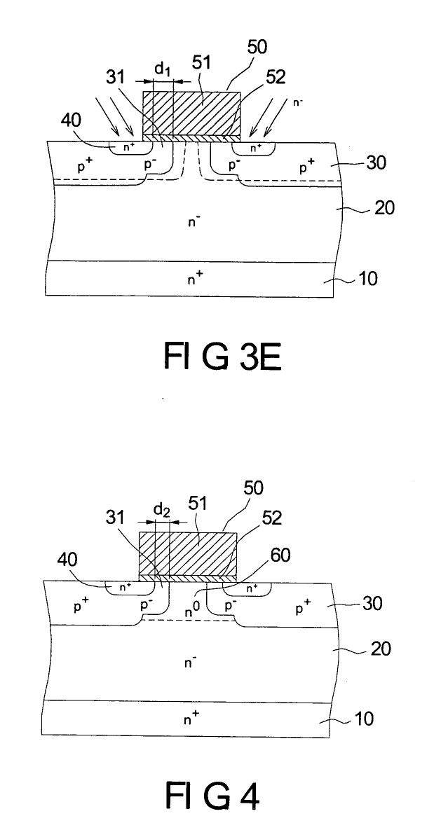

FIGS. 3A-3E shows a series of exemplary steps that are performed to form the n-channel DMOS structure depicted in FIG. 4.

In FIG. 3A, the n-channel DMOS transistor includes, in this embodiment, a semiconductor substrate 10 on which a low-concentration epitaxial region 20 of the first conductivity type (n-type) is grown. As described in more detail below, a single crystal silicon layer is formed on a surface of the semiconductor substrate 10 by means of a chemical reaction. The reaction gas (produced from the reaction between trichlorosilane and hydrogen) that is utilized flows over the surface of the semiconductor substrate 10 to form a boundary layer. Then, the epitaxial layer 20 is formed over the semiconductor substrate 10 after the reaction gas diffuses via the boundary layer.

As shown in FIG. 3B, a gate region 50 is formed adjacent to an upper surface of the epitaxial layer 20 by means of a series of processes, such as, a thin film process, a photolithography process, or an etching process, etc. The gate region 50 includes an insulating layer 52 and a polysilicon structure 51 extending over the insulating layer 52.

Next, as shown in FIG. 3C, one or more body regions 30 of a second conductivity type (p-type) are formed within the epitaxial layer 20 by the p-type dopant implanted into a top of the epitaxial layer 20 in an ion implantation and diffusion process. The body region 30 includes a high-concentration body region (p+ body) and a low-concentration body region (p− body) adjacent to one another.

In FIG. 3D, a plurality of high-concentration source regions 40 of the first conductivity type (n-type) are formed within the body regions 30 by the n-type dopant implanted into a top of the body region 30 in the ion implantation and diffusion step. The upper surface area of the body regions 30 between an outer edge of the body region 30 and the source region 40 (or a region directly underneath the gate region 50) is defined as a channel region 31. The horizontal length of the channel region is d₁.

FIG. 3E shows the step of introducing the dopant of the first conductivity type (n-type) into the JFET region above the epitaxial layer 20 in accordance with the present invention. By means of the ion implantation manner capable of inclinedly implanting angle and selective implanting depth, the dopant of the first conductivity type (n-type) can be inclinedly implanted into the JFET region above the epitaxial layer 20 for forming a medium-concentration epitaxial region 60 of the first conductivity type (n-type), as shown in FIG. 4. When the method is performed in its entirety, the step of forming the polysilicon structure 51 of the gate region 50 is performed prior to the inclinedly implanting step for blocking the dopant into the channel region 31. Thus, the dopant is not directly implanted into the channel region 31, and the threshold voltage and the breakdown voltage will not be reduced, so that the punch-through effect will also be avoided.

Furthermore, the horizontal length of the channel region 31 can be shortened to d₂ for decreasing the resistance in the channel region 31. When increasing the quantity of the dopant in the JFET region above the epitaxial layer 20, the resistance in the JFET region will be reduced, thereby achieving a decrease in the on-resistance of the power semiconductor device.

Although the invention has been described in the context of the n-channel DOMS transistor, forming other types of power semiconductor devices (for example, the p-channel DOMS transistor or the IGBT device) to obtain the benefits of the present invention would be obvious to one skilled in this art in view of the above teaching.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a power semiconductor device, comprising:
providing a substrate;
forming an epitaxial layer of a first conductivity type over said substrate;
forming a gate region adjacent to an upper surface of said epitaxial layer;
forming one or more body regions of a second conductivity type within said epitaxial layer;
forming a plurality of source regions of said first conductivity type within said body regions; wherein a surface area of said body region directly underneath said gate region is defined as a channel region; and
inclinedly implanting dopant of said first conductivity type into a JFET region above said epitaxial layer for forming a medium-concentration epitaxial region of said first conductivity type;
wherein said step of forming said gate region is performed prior to said inclinedly implanting step for blocking said dopant into said channel region.

2. The method of claim 1, wherein said power semiconductor device is an n-channel double-diffused metal oxide semiconductor (n-channel DMOS structure), said substrate is defined as a high-concentration drain region of said first conductivity type, said first conductivity type is n-type and said second conductivity type is p-type.

3. The method of claim 1, wherein said power semiconductor device is a p-channel double-diffused metal oxide semiconductor (p-channel DMOS structure), said substrate is defined as a high-concentration drain region of said first conductivity type, said first conductivity type is p-type and said second conductivity type is n-type.

4. The method of claim 1, wherein said power semiconductor device is an insulated gate bipolar transistor (IGBT structure), said substrate is defined as a high-concentration drain region of said second conductivity type, said first conductivity type is n-type and said second conductivity type is p-type.

5. A power semiconductor device having reduced on-resistance (Rₒₙ), comprising:
a substrate;
an epitaxial layer of a first conductivity type formed over said substrate;
a gate region formed adjacent to an upper surface of said epitaxial layer;
one or more body regions of a second conductivity type formed within said epitaxial layer;
a plurality of source regions of said first conductivity type formed within said body regions; wherein surface area of said body regions directly underneath said gate region is defined as a channel region; and
a medium-concentration epitaxial region of said first conductivity type formed by inclinedly implanting dopant of said first conductivity type into a JFET region above said epitaxial layer.

6. The power semiconductor device of claim 5, wherein said power semiconductor device is an n-channel double-diffused metal oxide semiconductor (n-channel DMOS structure), said substrate is defined as a high-concentration drain region of said first conductivity type, said first conductivity type is n-type and said second conductivity type is p-type.

7. The power semiconductor device of claim 5, wherein said power semiconductor device is a p-channel double-diffused metal oxide semiconductor (p-channel DMOS structure), said substrate is defined as a high-concentration drain region of said first conductivity type, said first conductivity type is p-type and said second conductivity type is n-type.

8. The power semiconductor device of claim 5, wherein said power semiconductor device is an insulated gate bipolar transistor (IGBT structure), said substrate is defined as a high-concentration drain region of said second conductivity type, said first conductivity type is n-type and said second conductivity type is p-type.

9. The power semiconductor device of claim 5, wherein said gate region includes an insulating layer and a polysilicon structure extending over said insulating layer.

10. The power semiconductor device of claim 5, wherein each of said body regions includes a high-concentration body region and a low-concentration body region adjacent to one another.
